(19) United States
(12) Patent Application Publication
(10) Pub. No.: US 2025/0088156 A1
(43) Pub. Date: Mar. 13, 2025

(54) INSTRUMENTATION AMPLIFIER CAPABLE OF COMPENSATING OFFSET VOLTAGE

(71) Applicant: Seoul National University R&DB Foundation, Seoul (KR)

(72) Inventors: Junyoung PARK, Suwon-si Gyeonggi-do (KR); Suhwan KIM, Seoul (KR)

(73) Assignee: Seoul National University R&DB Foundation, Seoul (KR)

(21) Appl. No.: 18/798,400

(22) Filed: Aug. 8, 2024

(30) Foreign Application Priority Data
Sep. 11, 2023 (KR) 10-2023-0120719

(51) Int. Cl. H03F 3/45

(52) U.S. Cl. CPC H03F 3/45479; H03F 2200/261; H03F 2200/375

(57) ABSTRACT

An instrumentation amplifier includes an input chopping circuit configured to convert differential input voltages into differential chopping input voltages according to a chopping signal; a compensation voltage input circuit configured to generate differential compensation voltages according to differential compensation signals; a compensation chopping circuit configured to generated signals by performing chopping operation on the differential compensation voltages according to the chopping signal and to provide the signals to the compensation voltage input circuit; an amplifier circuit configured to generate differential output voltages from the differential chopping input voltages and the differential compensation voltages; a modulation circuit configured to modulate the differential output voltages; an output chopping circuit configured to generate a bitstream signal by converting phase of an output of the modulation circuit according to the chopping signal; and a filter circuit configured to filter the bitstream signal.

### CROSS-REFERENCE TO RELATED APPLICATIONS

The present application claims priority under 35 U.S.C. § 119 (a) to Korean Patent Application No. 10-2023-0120719, filed in the Korean Intellectual Property Office on Sep. 11, 2023, which application is incorporated herein by reference in its entirety.

### BACKGROUND

### 1. Technical Field

Embodiments relate to an instrumentation amplifier, and more specifically, to an instrumentation amplifier capable of compensating an offset voltage.

### 2. Related Art

With the advent of the Internet of Things (IoT) era, research and development is underway on various smart devices and sensors.

Most sensors used for this purpose have the characteristic of outputting a very small signal in a low frequency band of several hertz, and are also referred to as DC sensors.

There is a demand for a semiconductor device that reads and outputs signals from these sensors and outputs low-power and high-resolution signals.

FIG. 1 is a circuit diagram showing a conventional instrumentation amplifier 1.

The conventional instrumentation amplifier 1 includes a first input amplifier 11, a second input amplifier 12, and an output amplifier 13, each of which is an operational amplifier.

A positive input voltage V_{INP} is applied to a positive input terminal of the first input amplifier 11, and a negative input voltage V_{INN} is applied to a positive input terminal of the second input amplifier 12.

A resistor R₁ is connected between an output terminal of the first input amplifier 11, that is, a first node N1, and a negative input terminal of the first input amplifier 11, that is, a second node N2, and the first resistor R₁ is connected between an output terminal of the second input amplifier 12, that is, a third node N3, and a negative input terminal of the second input amplifier 11, that is, 3a fourth node N4.

A variable resistor R_{G} is connected between the second node N2 and the fourth node N4.

A resistor R₂ is connected between the first node N1 and a positive input terminal of the output amplifier 13, that is, a fifth node N5, and a resistor R₂ is connected between the third node N4 and a negative input terminal of the output amplifier 13, that is, a sixth node N6.

A resistor R₃ is connected between the fifth node N5 and a negative output terminal of the output amplifier 13, and a resistor R₃ is connected between the sixth node N6 and a positive output terminal of the output amplifier 13.

Gain of the conventional instrumentation amplifier 1 is expressed as Equation 1.

$$Gain = \frac{{R}_{3}}{{R}_{2}} \times ( 1 + \frac{{R}_{1}}{{R}_{G}} ) \qquad [ Equation 1 ]$$

In the conventional instrumentation amplifier 1, the gain can be adjusted by adjusting the variable resistor R_{G}.

In the conventional instrumentation amplifier 1, if offset exists in the operational amplifiers, the offset voltage is amplified, the output voltage may be saturated, and the instrumentation amplifier 1 may not operate normally.

### SUMMARY

In accordance with an embodiment of the present disclosure, an instrumentation amplifier may include an input chopping circuit configured to convert differential input voltages into differential chopping input voltages according to a chopping signal; a compensation voltage input circuit configured to generate differential compensation voltages according to differential compensation signals; a compensation chopping circuit configured to generated signals by performing chopping operation on the differential compensation voltages according to the chopping signal and to provide the signals to the compensation voltage input circuit; an amplifier circuit configured to generate differential output voltages from the differential chopping input voltages and the differential compensation voltages; a modulation circuit configured to modulate the differential output voltages; an output chopping circuit configured to generate a bitstream signal by converting phase of an output of the modulation circuit according to the chopping signal; and a filter circuit configured to filter the bitstream signal.

### BRIEF DESCRIPTION OF THE DRAWINGS

The accompanying figures, where like reference numerals refer to identical or functionally similar elements throughout the separate views, together with the detailed description below, are incorporated in and form part of the specification, and serve to further illustrate embodiments that include various features, and explain various principles and beneficial aspects of those embodiments.

FIG. 1 illustrates a conventional instrumentation amplifier.

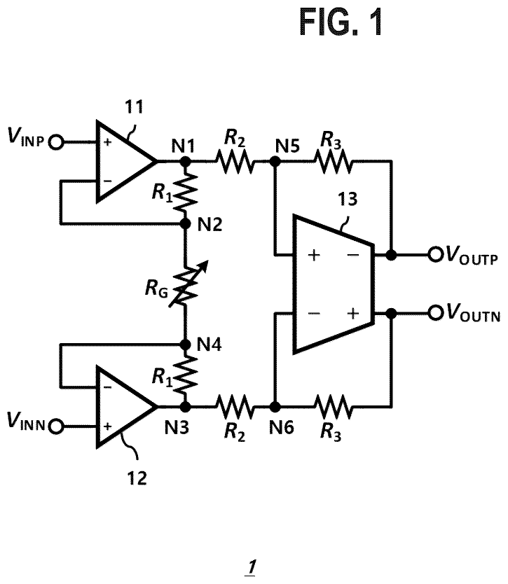

FIG. 2 illustrates an instrumentation amplifier according to an embodiment of the present disclosure.

FIG. 3 is a timing diagram showing an operation of an instrumentation amplifier according to an embodiment of the present disclosure.

FIGS. 4A and 4B are graphs showing an effect of an instrumentation amplifier according to an embodiment of the present disclosure.

### DETAILED DESCRIPTION

Various embodiments will be described below with reference to the accompanying figures. Embodiments are provided for illustrative purposes and other embodiments that are not explicitly illustrated or described are possible. Further, modifications can be made to embodiments of the present disclosure that will be described below in detail.

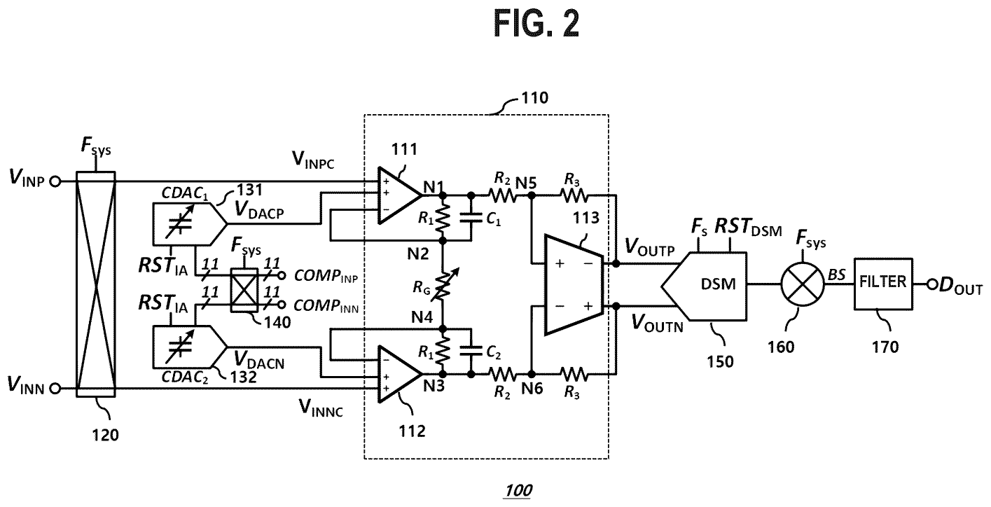

FIG. 2 is a circuit diagram showing an instrumentation amplifier 100 according to an embodiment of the present disclosure.

The instrumentation amplifier 100 includes an amplifier circuit 110, an input chopping circuit 120, a first compensation voltage input circuit 131, a second compensation voltage input circuit 132, and a compensation input chopping circuit 140, a modulation circuit 150, an output chopping circuit 160, and a filter circuit 170.

The amplifier circuit 110 includes a first input amplifier 111, a second input amplifier 112, and an output amplifier 113, each of which is an operational amplifier.

The first input amplifier 111 and the second input amplifier 112 differ from conventional circuits in that a positive input terminal where an input compensation voltage is input is added, respectively.

In this embodiment, each of the first input amplifier 111 and the second input amplifier 112 may be implemented with a differential difference amplifier DDA. Since the DDA itself is a conventional technology, detailed description thereof will be omitted.

A positive chopping input voltage V_{INPC} is applied to a first positive input terminal of the first input amplifier 111, and a positive compensation voltage V_{DACP} is applied to a second positive input terminal of the first input amplifier 111.

A negative chopping input voltage V_{INNC} is applied to a first positive input terminal of the second input amplifier 112, and a negative compensation voltage V_{DACN} is applied to a second positive input terminal of the second input amplifier 112.

A resistor R₁ and a capacitor C₁ are connected in parallel between an output terminal of the first input amplifier 111, that is, a first node N1, and a negative input terminal of the first input amplifier 111, that is, a second node N2.

A resistor R₁ and a capacitor C₂ are connected in parallel between an output terminal of the second input amplifier 112, that is, a third node N3, and a negative input terminal of the second input amplifier 112, that is, a fourth node N4.

A variable resistor R_{G} is connected between the second node N2 and the fourth node N4.

A resistor R₂ is connected between the first node N1 and a positive input terminal of the output amplifier 113, that is, a fifth node N5, and a resistor R₂ is connected between the third node N3 and a negative input terminal of the output amplifier 113, that is, a sixth node N6.

A resistor R₃ is connected between the fifth node N5 and a negative output terminal of the output amplifier 113, and a resistor R₃ is connected between the sixth node N6 and a positive output terminal of the output amplifier 113.

A gain Av of the amplifier circuit 100 is expressed as Equation 2 below. The gain Av can be adjusted by adjusting the variable resistor R_{G} in the amplifier circuit 100.

$${A}_{v} = \{ \frac{{g}_{m , in}}{{g}_{m , in} + {g}_{m , offset}} ( {V}_{INPC} - {V}_{INNC} ) + \frac{{g}_{m , offset}}{{g}_{m , in} + {g}_{m , offset}} ( {V}_{DACP} - {V}_{DACN} ) \} ( 1 + \frac{{R}_{1}}{{R}_{G}} ) ( \frac{{R}_{3}}{{R}_{2}} ) \qquad [ Equation 2 ]$$

In Equation 2, g_{m,in} is a transconductance corresponding to the input voltage in the DDA circuit, and g_{m,offset} is a transconductance corresponding to an offset voltage in the DDA circuit.

The input chopping circuit 120 performs a chopping operation according to a chopping signal F_{sys}, receives input voltages V_{INP} and V_{INN}, and outputs chopping input voltages V_{INPC} and V_{INNC}.

For example, when the chopping signal F_{sys} is at a high level, a positive input voltage V_{INP} corresponds to the positive chopping input voltage V_{INPC} and a negative input voltage V_{INN} corresponds to the negative chopping input voltage V_{INNC}. Conversely, when the chopping signal F_{sys} is at a low level, the positive input voltage V_{INP} corresponds to the negative chopping input voltage V_{INNC} and the negative input voltage V_{INN} corresponds to the positive chopping input voltage V_{INPC}.

The first compensation voltage input circuit 131 generates the positive compensation voltage V_{DACP} and the negative compensation voltage V_{DACN} according to a positive compensation signal COMP_{INP} and a negative compensation signal COMP_{INN}. The second compensation voltage input circuit 132 generate the negative compensation voltage V_{DACN} according to the positive compensation signal COMP_{INP} and the negative compensation signal COMP_{INN}.

In this embodiment, each of the positive compensation signal COMP_{INP} and the negative compensation signal COMP_{INN} is a 11-bit digital signal, and each of the first compensation voltage input circuit 131 and the second compensation voltage input circuit 132 includes a digital-to-analog converter.

The compensation input chopping circuit 140 provides the compensation signals COMP_{INP} and COMP_{INN} to the first compensation voltage input circuit 131 and the second compensation voltage input circuit 132 according to the chopping signal F_{sys}.

For example, when the chopping signal F_{sys} is at the high level, the positive compensation signal COMP_{INP} is provided to the first compensation voltage input circuit 131, and the negative compensation signal COMP_{INN} is provided to the second compensation voltage input circuit 132. Conversely, when the chopping signal F_{sys} is at the low level, the positive compensation signal COMP_{INP} is provided to the second compensation voltage input circuit 132, and the negative compensation signal COMP_{INN} is provided to the first compensation voltage input circuit 131.

When the first reset signal RST_{IA} is activated, the first compensation voltage input circuit 131 and the second compensation voltage input circuit 132 output voltages at the same level.

In this embodiment, the modulation circuit 150 is an incremental delta sigma modulator that modulates differential output voltages V_{OUTP} and V_{OUTN} output from the amplifier circuit 110. The incremental delta sigma modulator itself is well known, so detailed description thereof will be omitted.

The modulation circuit 150 performs a modulation operation according to the modulation signal Fₛ and is initialized by the second reset signal RST_{DSM}.

The output chopping circuit 160 generates a bit stream signal BS by changing phase of an output of the modulation circuit 150 according to the chopping signal F_{sys}.

For example, if the chopping signal F_{sys} is at the high level, the output of the modulation circuit 150 generates the bit stream signal BS as is. Conversely, when the chopping signal F_{sys} is at the low level, the phase of the output of the modulation circuit 150 is changed by 180 degrees to generate the bit stream signal BS.

The filter circuit 170 filters the bit stream signal BS and generates a digital output signal D_{OUT}.

In this embodiment, the filter circuit 170 performs digital decimation filtering and averages the two outputs resulting from the chopping operation to generate one digital output signal D_{OUT}. Since the operation of the digital decimation filter itself is well known, detailed description thereof will be omitted.

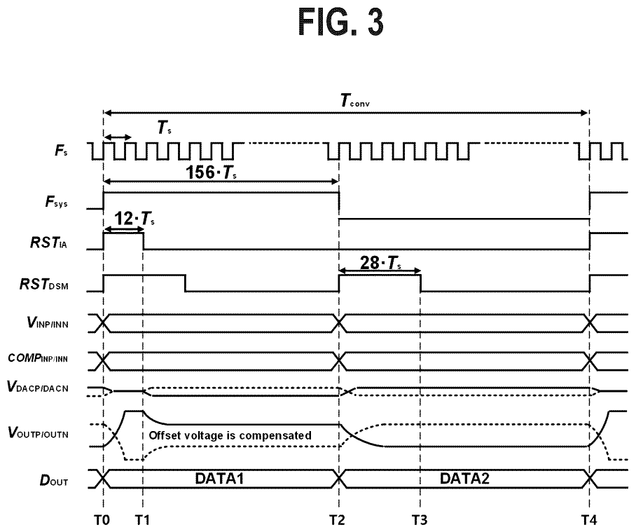

FIG. 3 is a timing diagram showing an operation of the instrumentation amplifier 100 according to an embodiment of the present disclosure.

The modulation signal Fₛ has a modulation period T_{S}, and the modulation circuit 150 performs sampling and modulation operations accordingly.

The chopping signal F_{sys} has a conversion period T_{conv} and the chopping operation is performed accordingly. The modulation period T_{conv} corresponds to 212 times the modulation period T_{S}.

The first reset signal RST_{IA} resets the amplifier circuit 110 in the high level section between T0 and T1, which is 12 times the modulation period T_{S}, and at this time, as described above, the first compensation voltage input circuit 131 and the second compensation voltage input circuit 132 output voltages at the same level.

The second reset signal RST_{DSM} resets the modulation circuit 150 in the high level section between T2 and T3, which is 28 times the modulation period T_{S}. During this time, the output voltages V_{OUTP} and V_{OUTN} of the amplifier circuit 110 are sufficiently stabilized.

In FIG. 3, a section between T0 and T4 correspond to one modulation period T_{conv}.

From T0 to T2, the modulation signal F_{sys} is at the high level and the first operation is performed accordingly, and the filter circuit 170 generates a first data DATA1 accordingly.

From T2 to T4, the modulation signal F_{sys} is at the low level and a second operation is performed accordingly, and the filter circuit 170 generates a second data DATA2 accordingly.

The filter circuit 170 averages the first data DATA1 and the second data DATA2 to generate a final digital output signal D_{OUT} corresponding to the modulation period T_{CONV}.

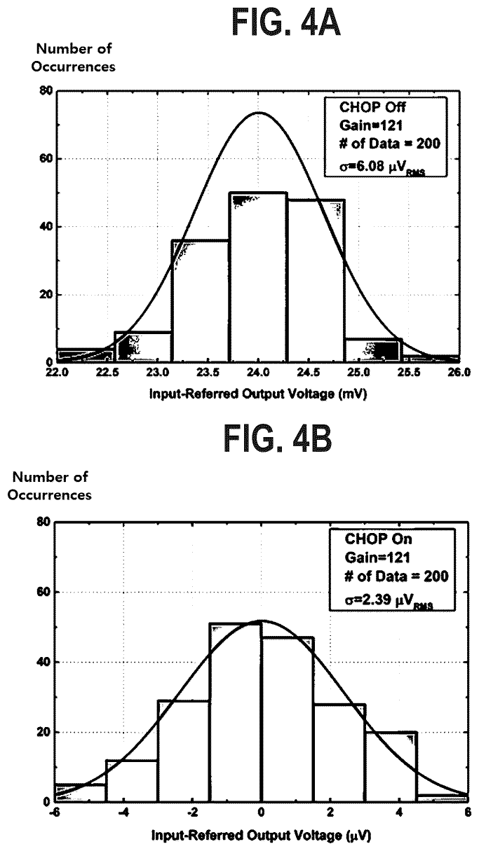

FIGS. 4A and 4B are graphs showing measured noise of the instrumentation amplifier 100 according to an embodiment of the present disclosure.

FIG. 4A corresponds to a case where the chopping operation is not performed, and FIG. 4B corresponds to a case where the chopping operation is performed.

In FIGS. 4A and 4B, the gain of the amplifier circuit 100 is 121, the number of data is 200, and the offset voltage is 24 mV.

In the graphs, the horizontal axis corresponds to the output voltage corresponding to the input voltage, and the vertical axis represents the number of cases corresponding to the range of the output voltage.

When the chopping operation is not performed as in FIG. 4A, the output is distributed around 24 mV, and in this case, the standard deviation and input referred noise is 6.08 μV_{RMS}. The input-referred noise corresponds to noise divided by the gain of the amplifier circuit 100.

When the chopping operation is performed as shown in FIG. 4B, the output is distributed around 0V, and in this case, the standard deviation and input reference noise is 2.39 μV_{RMS}.

It can be seen that by performing the chopping operation in this way, the influence of the offset voltage is reduced and the noise characteristics are improved.

Although various embodiments have been described for illustrative purposes, it will be apparent to those skilled in the art that various changes and modifications may be made to the described embodiments without departing from the spirit and scope of the disclosure as defined by the following claims.

What is claimed is:

1. An instrumentation amplifier comprising:
an input chopping circuit configured to convert differential input voltages into differential chopping input voltages according to a chopping signal;
a compensation voltage input circuit configured to generate differential compensation voltages according to differential compensation signals;
a compensation chopping circuit configured to generated signals by performing chopping operation on the differential compensation voltages according to the chopping signal and to provide the signals to the compensation voltage input circuit;
an amplifier circuit configured to generate differential output voltages from the differential chopping input voltages and the differential compensation voltages;
a modulation circuit configured to modulate the differential output voltages;
an output chopping circuit configured to generate a bitstream signal by converting phase of an output of the modulation circuit according to the chopping signal; and
a filter circuit configured to filter the bitstream signal.

2. The instrumentation amplifier of claim 1, wherein the amplifier circuit includes:
a first input amplifier configured to receive a positive input voltage among the differential chopping input voltages and a positive compensation voltage among the differential compensation voltages via two positive input terminals;
a second input amplifier configured to receive a negative input voltage among the differential chopping input voltages and a negative compensation voltage among the differential compensation voltages via two positive input terminals; and
an output amplifier configured to generate the differential output voltages.

3. The instrumentation amplifier of claim 2, wherein the amplifier circuit further includes:
a resistor and a capacitor connected in parallel between a negative input terminal of the first input amplifier and an output terminal of the first input amplifier;
a resistor and a capacitor connected in parallel between a negative input terminal of the second input amplifier and an output terminal of the second input amplifier; and
a variable resistor connected between the negative input terminal of the first input amplifier and the negative input terminal of the second input amplifier.

4. The instrumentation amplifier of claim 2, wherein the amplifier circuit further includes:
a resistor connected between an output terminal of the first input amplifier and a positive input terminal of the output amplifier;
a resistor connected between an output terminal of the second input amplifier and a negative input terminal of the output amplifier; and
a resistor connected between the positive input terminal of the output amplifier and a negative output terminal of the output amplifier; and
a resistor connected between the negative input terminal of the output amplifier and a positive output terminal of the output amplifier.

5. The instrumentation amplifier of claim 1, wherein the filter circuit generates an average of a first value and a second value as an output thereof, and
wherein the first value corresponds to an output of the filter circuit during a first operation performed when the chopping signal has a high level and the second value corresponds to an output of the filter circuit during a second operation performed when the chopping signal has a low level.

6. The instrumentation amplifier of claim 5, wherein the compensation voltage input circuit sets the differential compensation voltages at the same level when a first reset signal is enabled.

7. The instrumentation amplifier of claim 6, wherein the modulation circuit performs an initialization operation when a second reset signal is enabled.

8. The instrumentation amplifier of claim 7, wherein the first reset signal is enabled at the beginning of the first operation and the second reset signal is enabled at the beginning of the second operation.
